(19) United States
(12) Patent Application Publication
(10) Pub. No.: US 2017/0257066 A1
(43) Pub. Date: Sep. 7, 2017

(54) SYSTEMS AND METHODS FOR COMPENSATING FOR VARIATION IN AN AMPLITUDE-REGULATED OSCILLATOR

(71) Applicant: QUALCOMM Incorporated, San Diego, CA (US)

(72) Inventors: NITZ SAPUTRA, San Diego, CA (US); Sang Min Lee, San Diego, CA (US); Dongwon Seo, San Diego, CA (US)

(21) Appl. No.: 15/188,552

(22) Filed: Jun. 21, 2016

Related U.S. Application Data
(60) Provisional application No. 62/302,374, filed on Mar. 2, 2016.
(60) Provisional application No. 62/337,234, filed on May 16, 2016.

(51) Int. Cl. H03B 5/26; H03B 5/04

(52) U.S. Cl. CPC H03B 5/26; H03B 5/04

(57) ABSTRACT

Circuits and methods for compensating variation in an amplitude-regulated oscillator are provided. In one example, the oscillator includes a diode clamp having back-to-back diode-connected transistors with body terminals. Circuits and methods modulate a body-source voltage of the diode-connected transistors to compensate for process, temperature, and voltage variation.

### CROSS-REFERENCE TO RELATED APPLICATIONS

The present application claims the benefit of U.S. Provisional Patent Application No. 62/302,374, filed Mar. 2, 2016, and entitled “Systems and Methods for Compensating for Variation in an Amplitude-Regulated Oscillator,” and claims the benefit of U.S. Provisional Patent Application No. 62/337,234, filed May 16, 2016, and entitled “Systems and Methods for Compensating for Variation in an Amplitude-Regulated Oscillator,” the disclosures of which are incorporated by reference herein in their entirety.

### TECHNICAL FIELD

This application relates to oscillators, and more particularly, to variation compensation in amplitude-regulated oscillators.

### BACKGROUND

Process, voltage, and temperature variation (PVT variation) is a concept that is often applied to semiconductor devices. PVT variation includes a variety of different phenomenon. For instance, process variation refers to behavioral differences in a semiconductor device that are attributable to manufacturing. Voltage variation refers to behavioral differences in a semiconductor device from one operating voltage to another operating voltage. Similarly, temperature variation refers to behavioral differences in a semiconductor device from one operating temperature to another operating temperature. In many instances, PVT variation may cause undesirable effects, but it can often be accounted for or compensated.

Oscillators are a type of device that may be built on a semiconductor substrate and may experience PVT variation. For example, a Wien bridge oscillator includes impedances Z1 and Z2, which have resistors and capacitors therein. It is these resistors and capacitors that may be affected by PVT variation. Additionally, a Wien bridge oscillator includes an amplifier, the output of which provides the voltage output (Vout), which generate a clock signal d_clock_out.

A known problem with the Wien bridge oscillator is that its amplitude is somewhat unregulated, thereby causing a phenomenon called “clipping,” where output signals are outside of a maximum allowable design range. PVT variation causes a change in behavior of the amplifier in the oscillator as well, and clipping increases sensitivity to the amplifier behavioral changes.

In an application that measures and RC product of the impedances, clipping may cause inaccuracies and errors in measuring the RC product because clipping makes it difficult to separate the effects of process variation on, the RC behavior versus the effects of process variation on behavior of the amplifier. Therefore, some conventional solutions provide amplitude regulation by use of a diode clamp. In theory, with, the amplitude regulation provided by the diode clamp, a more accurate measurement of the RC product should be possible.

An example diode clamp in a Wien bridge oscillator may be provided by back-to-back diodes. However, diodes add process variation too, thereby potentially adding inaccuracies to the RC product measurement. There is no conventional RC oscillator that provides amplitude regulation without further complicating the RC product calculation.

### SUMMARY

According to one embodiment, a circuit includes an oscillator, a diode clamp implemented in the oscillator and configured to regulate an amplitude of the oscillator, wherein the diode clamp includes a plurality of diode-connected transistors, each of the diode-connected transistors including a body terminal; and a compensation circuit in communication with the diode clamp and configured to modulate a body-source voltage of the diode-connected transistors in accordance with a current or voltage level of a transistor in the compensation circuit.

According to another embodiment, a method is performed by a circuit having an oscillator, and the method includes receiving a common mode voltage (V_{CM}) at the oscillator, wherein the oscillator includes a plurality of diode-connected transistors receiving V_{CM} at their respective source terminals; receiving a body bias voltage at body terminals of the diode-connected transistors; regulating an amplitude of an output clock signal of the oscillator by the diode-connected transistors; and modulating a body-source voltage (V_{BS}) of the diode-connected transistors in accordance with a voltage or current level of a transistor in a compensation circuit in communication with the oscillator.

According to another embodiment, a circuit includes means for generating a clock signal; means for regulating an amplitude of the clock signal generating means, the regulating means including coupled diodes having diode-connected transistors, each of the diode-connected transistors including a body terminal receiving a body bias voltage; and means for modulating a body-source voltage of the diode-connected transistors in accordance with a gate voltage level of a transistor in the modulating means.

According to another embodiment, a circuit includes a Wien bridge oscillator; a diode clamp in communication with the Wien bridge oscillator, the diode clamp including a plurality of diode-connected transistors, each of the diode-connected transistors having a body terminal receiving a body bias voltage and having a source terminal receiving a common mode voltage; and a compensation circuit in communication with the Wien bridge oscillator, the compensation circuit including a plurality of series-connected diodes having a voltage drop configured to adjust a body-source voltage of the diode connected transistors.

### BRIEF DESCRIPTION OF THE DRAWINGS

FIG. 1 illustrates an example system into which oscillators of the various embodiments may be implemented, in accordance with an embodiment of the disclosure.

FIG. 2 illustrates an example oscillator, which may be adapted for use in the system of FIG. 1, according to one embodiment.

FIG. 3 illustrates an example oscillator, which may be adapted for use in the system of FIG. 1, according to one embodiment.

FIG. 4 illustrates an example oscillator, which may be adapted for use in the system of FIG. 1, according to one embodiment.

FIG. 5 illustrates an example oscillator, which may be adapted for use in the system of FIG. 1, according to one embodiment.

FIG. 6 illustrates an example oscillator, which may be adapted for use in the system of FIG. 1, according to one embodiment.

FIG. 7 illustrates an example method according to one embodiment.

### DESCRIPTION

Various embodiments provide an oscillator having a PVT compensation circuit. In one example, the PVT compensation circuit includes one or more diode-connected transistors. Furthermore, the oscillator includes a diode clamp, where the diode clamp includes back-to-back diode-connected transistors. The PVT compensation circuit produces a voltage that affects a body-source voltage of the back-to-back diode-connected transistors of the diode clamp.

PVT variation affecting the diode-connected transistors of the PVT compensation circuit would generally be expected to affect the back-to-back diode-connected transistors of the diode clamp in a same or similar manner. Accordingly, the transistors of the PVT compensation circuit are selected so that they produce a voltage that affects a body-source voltage of the back-to-back, diode-connected transistors of the diode clamp in a way that offsets that same PVT variation at the back-to-back diode-connected transistors.

Continuing with the example, one particular embodiment includes the PVT compensation circuit having two diode-connected transistors in series with a current source. PVT variation affects a voltage drop across the diode-connected transistors. A voltage taken after the voltage drop from the diode-connected transistors is provided to the body terminals of the back-to-back diode-connected transistors of the diode clamp. PVT variation reducing a gate voltage of the transistors of the PVT compensation circuit would cause an incremental increase in the voltage applied to the body terminals of the transistors of the diode clamp. This incremental increase in the body terminal bias would compensate for the PVT variation affecting the transistors of the diode clamp.

In another embodiment, the voltage from the PVT compensation circuit may be applied as a common mode voltage to the oscillator, and the body terminals of the transistors of the diode clamp may be held at VDD. In this way, the voltage from the PVT compensation circuit is not directly applied to the body terminals of the transistors at the diode clamp, but the voltage from the PVT compensation circuit affects the body-source voltages of those transistors in a way that compensates for PVT variation.

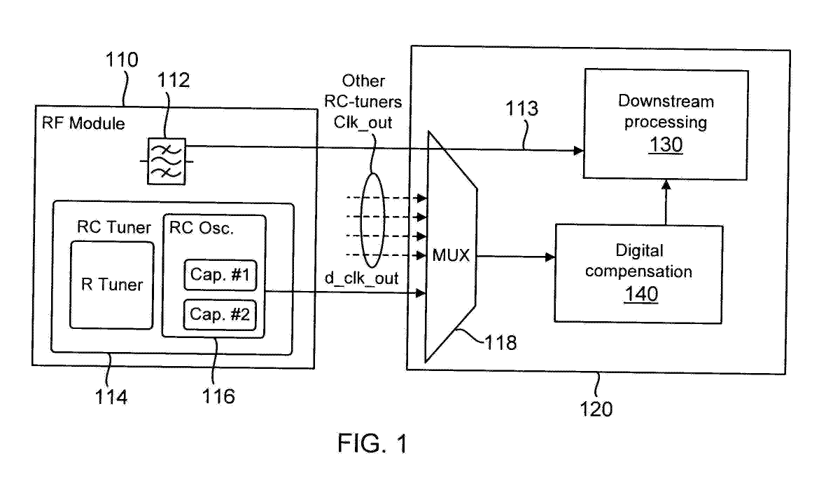

Various embodiments further include methods for compensating PVT variation of transistors in an oscillator. Such example methods may include, among other things, adjusting a body-source voltage of back-to-back diode-connected transistors of an oscillator to compensate for PVT variation. The various embodiments are described in more detail further below with respect to FIGS. 1-7.

FIG. 1 shows a system that includes a radio frequency (RF) module 110 and a digital module 120. The RF module 110 has a number of components, including a baseband filter (BBF) 112 that communicates with the digital module 120. The baseband filter 112 includes resistive and capacitive components that are affected by PVT variation.

In the system of FIG. 1, the RF module 110 processes an input signal with the baseband filter 112 and outputs a filtered signal 113 to the digital module 120. However, PVT variation may affect the RC components of the baseband filter 112, thereby affecting the filtered signal 113. The system of FIG. 1, therefore, calibrates itself by measuring the RC components and passing information about the RC components to the digital module 120 in the d_clock_out signal. Specifically, the RC oscillator 116 includes resistors and capacitors that are assumed to have a similar process variation as the resistors and capacitors in the baseband filter 112. The RC oscillator 116 produces a clock signal at a rate inversely proportional to the RC product, so that the rate of the clock is also affected by the same process variation. The clock signal produced by the oscillator is the d_clock_out signal. The digital module 120 receives the d_clock_out signal along with the filtered signal 113 and processes the filtered signal 113, making any appropriate adjustments according to the measured RC product, as indicated by d_clock_out.

Specifically, the baseband filter 112 provides the filtered signal 113 to downstream processing circuitry 130. Downstream processing circuitry 130 is simplified for ease of illustration in this example and may include appropriate circuits, such as mixers and the like. The d_clock_out signal is received by digital compensation circuit 140, which measures the d_clock_out signal in, the digital domain and provides corresponding digital adjustment signals to the downstream processing circuitry 130. Therefore, digital compensation circuit 140 allows downstream processing circuitry to adjust itself to compensate for PVT variation in the baseband filter 112. In another example, either the digital compensation circuit 140 or another component measures d_clock_out and tunes the baseband filter 112 by adjusting either its resistive or capacitive properties to compensate for variation.

Some embodiments include more than one RF module 110. Accordingly, the example of FIG. 1 includes multiplexer 118 to select a signal (Clk_out) from a desired RF module.

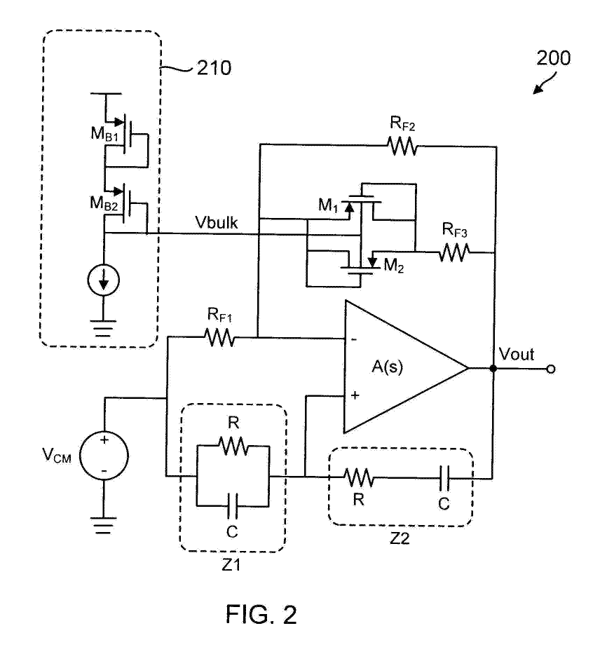

The RC oscillator 116 may be configured using any appropriate oscillator architecture, and in this example it is configured using a Wien bridge oscillator architecture. Furthermore, the oscillator includes a diode clamp to prevent clipping. Various embodiments herein regulate a body-source voltage of transistors in the diode clamp, to compensate PVT variation, in those transistors and provide more precise measurement of the RC product. A first example oscillator 200, which may be adapted as oscillator 116 of FIG. 1, is shown at FIG. 2. In the example of FIG. 2, the output voltage of the oscillator 200 is labeled Vout, and it corresponds to the clock signal d_clock_out signal of FIG. 1.

In the example of FIG. 2, the back-to-back diodes are implemented using diode-connected MOSFET transistors M1 and M2. For instance, M1 and M2 are coupled source-to-drain and drain-to-source, and the body terminals of M1 and M2 are coupled to a common node receiving voltage Vbulk. MOSFET transistors M1 and M2 include body terminals that are biased by the voltage Vbulk. PVT compensation circuit 210 includes transistors MB1 and MB2. Transistors MB1 and MB2 are arranged as diodes that provide a voltage drop that defines Vbulk. In this example it is assumed that PVT variation affecting diodes MB1 and MB2 affects diodes M1 and M2 in a similar manner. Accordingly, PVT variation that would reduce a gate voltage of MB1 and MB2 increases the value of Vbulk. The increased value of Vbulk biases the body terminals of M1 and M2 and changes the body-source voltages (VBS) to compensate for the PVT variation. Similarly, process variation that would increase a gate voltage of MB1 and MB2 decreases the value of Vbulk and also changes the body-source voltages of M1 and M2. Or, put another way, when PMOS VTH reduces, e.g. due to temperature changes, Vbulk will increase and so does body effect according to Equation 1 on M1 and M2, compensating for the earlier VTH reduction (and vice versa). VCM is a common mode voltage applied to the source terminals of transistors M1 and M2. The embodiment of FIG. 2 reduces or eliminates the diode variation complication of the system of FIG. 1.

VBS=Vbulk−VCM Equation 1

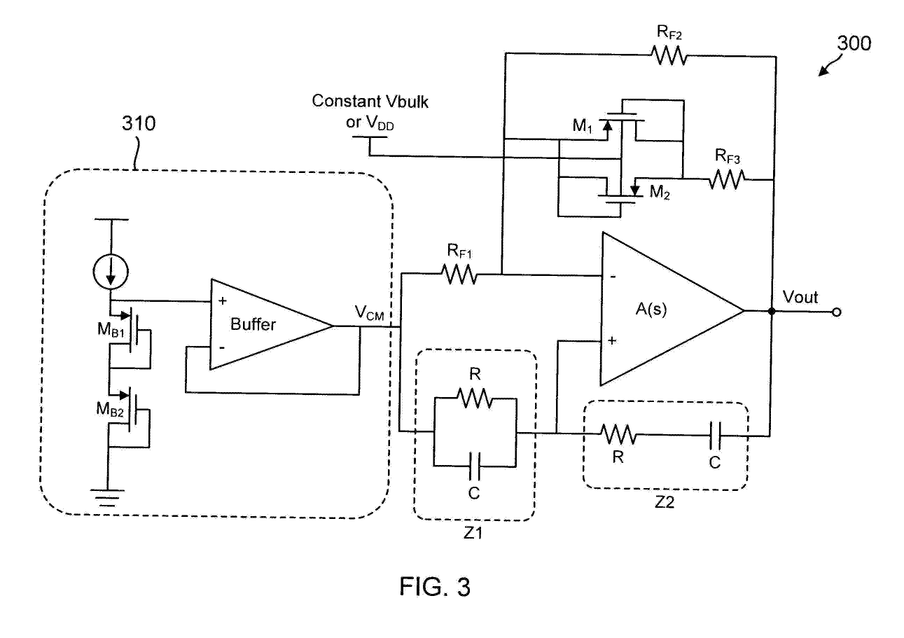

A second embodiment for regulating the body-source voltage of the diodes is shown in FIG. 3. FIG. 3 illustrates an example oscillator 300, which may be adapted as oscillator 116 of FIG. 1, according to one embodiment. PVT compensation circuit 310 produces a voltage VCM. Further, in this example, Vbulk is held at VDD, and the relationship at Equation 1 still holds true for the body-source voltages (VBS) at transistors M1 and M2: VBS=Vbulk(VDD)−VCM. Accordingly, the embodiment of FIG. 3 regulates VBS by adjusting VCM and provides the same benefits as the embodiment of FIG. 2.

As VTH of the transistors MB1 and MB2 decreases, so does VCM, which increases VBS of the transistors M1 and M2 and compensates for the decrease in VTH. Vice versa is true as well.

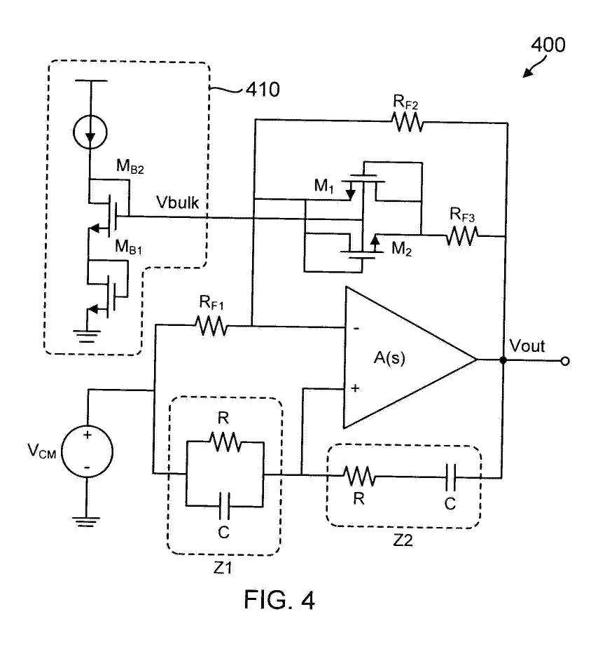

Depending on VCM, NMOS can be used instead of PMOS in the embodiments of FIGS. 2 and 3, and such modification may include eliminating or reducing forward bias in the source/drain to bulk by using an N well. FIG. 4 is an illustration of an example oscillator 400, which may be adapted for use as oscillator 116 of FIG. 1, according to one embodiment. For instance, the embodiment of FIG. 4 illustrates an embodiment similar to that of FIG. 2, but implemented using NMOS transistors. Oscillator 400 includes a PVT compensation circuit 410, which generates the voltage Vbulk. Of note in FIG. 4 is that the Vbulk direction for compensation is opposite that of the PMOS embodiment of FIG. 2. Manufacturing the embodiment of FIG. 4 may involve a deep N-well feature, which may be less cost efficient than the embodiment of FIG. 2.

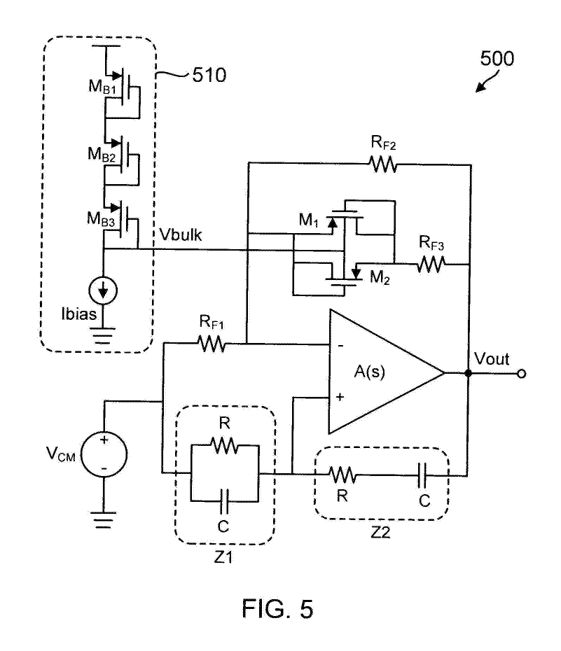

Another alternative embodiment is shown in FIG. 5. FIG. 5 illustrates an example oscillator 500, which may be adapted for use as oscillator 116 of FIG. 1, according to one embodiment. The embodiment of FIG. 5 is similar to the embodiment of FIG. 2, except that the embodiment of FIG. 5 includes three compensation transistors (MB1, MB2, and MB3) in PVT compensation circuit 510. Once again, as in the embodiment of FIG. 2, the voltage drop caused by the series diode-connected transistors of PVT compensation circuit 510 generates the voltage Vbulk. Changes in Vbulk, either up or down, therefore change the body-source voltages of transistors M1 and M2 to compensate for PVT variation.

The embodiment of FIG. 5 improves sensitivity of Vbulk to PVT variation. However, the embodiment of FIG. 5 would use more space on a die to manufacture and be limited by the supply voltage.

FIG. 5 illustrates that various embodiments shown herein using two compensation transistors may be built using a different number of compensation transistors, such as one, three, or more than three. For example, the embodiment of FIG. 5 can also be modified to include more or fewer compensation transistors. Various embodiments may use any appropriate number of compensation transistors.

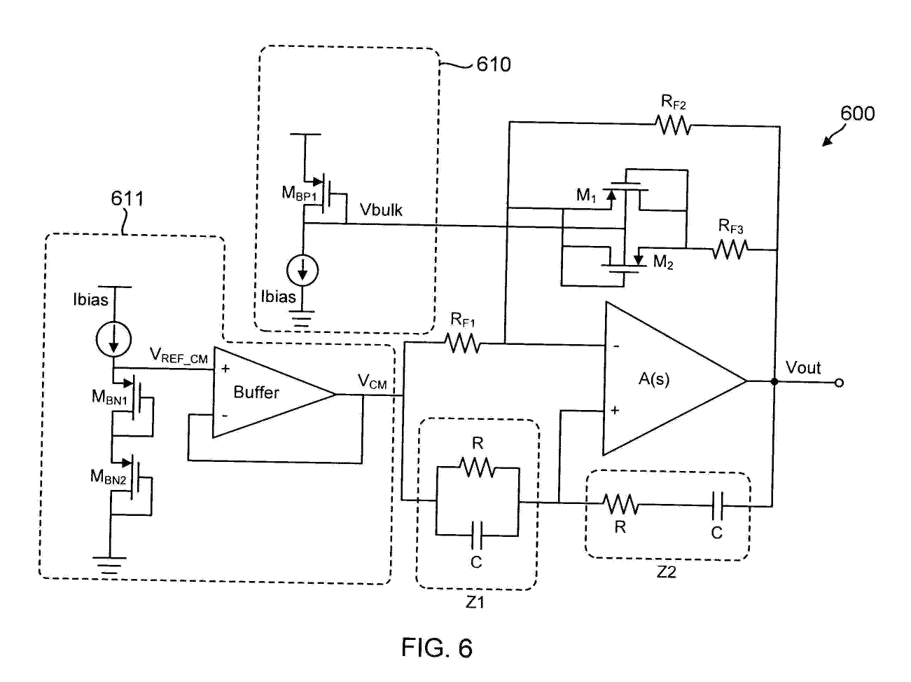

Each of the embodiments described above modulate either of Vbulk or VCM to compensate for PVT variation of the diode connected transistors in the oscillator 116. FIG. 6 is an illustration of an example oscillator 600, which may be adapted for use as oscillator 116 of FIG. 1, according, to one embodiment. FIG. 6 is an embodiment that modulates both Vbulk and VCM to compensate for PVT variation. Specifically, both Vbulk and VCM affect VBS, and the relationship shown in Equation 1 still holds true in the embodiment of FIG. 6. Accordingly, the compensation transistors and FIG. 6 (MBP1, MBN1, MBN2) are chosen to provide voltage drops with the constraints of Equation 1 in mind; this is true for the other embodiments described herein as well. Also, NMOS variations of any of the embodiments herein may be built as well, keeping in mind that the Vbulk and VCM directions for compensation or opposite that of the PMOS embodiments.

While the embodiments herein are applied to Wien bridge oscillators, the scope of embodiments is not so limited. Rather, the embodiments shown and described may be adapted for use with any appropriate oscillator having a diode clamp.

Various embodiments may include advantages over conventional systems. For instance, the embodiments described above may allow for the measurement of the RC product of the oscillator 116 with more precision, compared to conventional systems which may have clipping or be subject to diode variation.

The scope of embodiments includes methods for use of the oscillators described above and in FIGS. 1-6. One example method includes outputting a clock signal from an oscillator, where the oscillator is an amplitude-regulated oscillator (e.g., diode-clamped) having PVT variation compensation therein. As the oscillator operates, either or both of VCM or Vbulk are modulated to compensate for PVT variation of transistors acting as a diode clamp. Examples of modulating either or both of VCM or Vbulk are described above with respect to FIGS. 2-6. Furthermore, diodes in the oscillator regulate the amplitude of the output clock signal to prevent clipping.

The method continues with downstream components receiving the output clock signal. The clock signal provides an indication of behavior of a filter (e.g., such as a baseband filter), built on a same substrate as the oscillator. Specifically, in the examples above, the output clock signal provides an indication of an RC product of the oscillator, where the RC product is also expected to be indicative of the behavior of the filter. The downstream components then use information from the output clock signal, for example in the digital domain, to calibrate their operation as they process a signal received from the filter. Of course, the scope of embodiments is not limited to the specific method, as the method may be used to provide an indication of an RC product of any filter, not just a baseband filter.

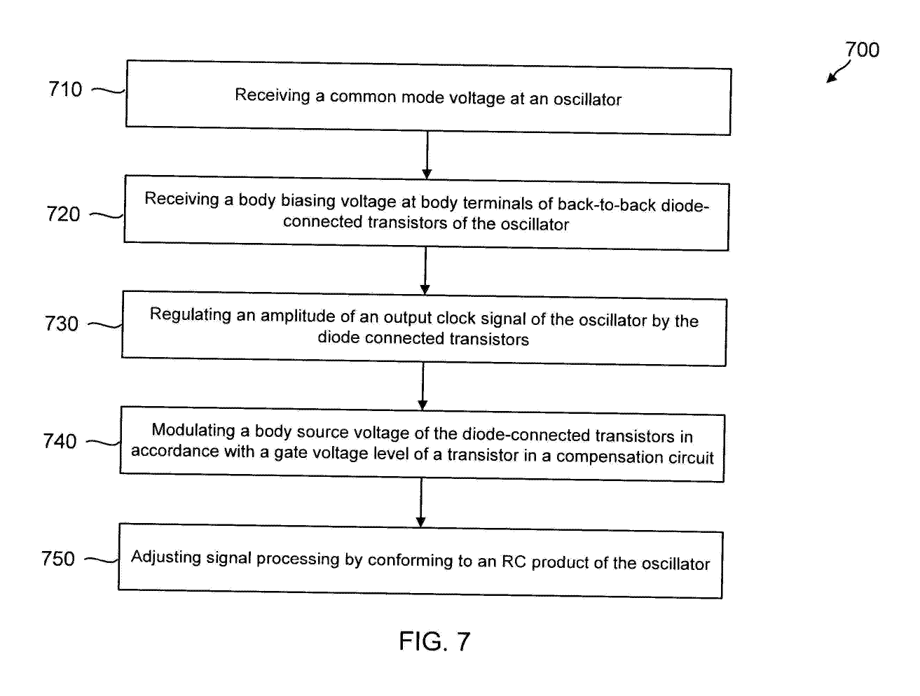

FIG. 7 is an illustration of an example method 700, adapted according to one embodiment. Method 700 may be performed by the circuit of FIG. 1.

At action 710, the oscillator receives a common mode voltage. The oscillator includes back-to-back diode-connected transistors receiving the common mode voltage at their respective source terminals. Examples are shown in FIGS. 2-6, in which Wien bridge oscillators receive a common mode voltage VCM.

At action 720, the body terminals of the back-to-back diode-connected transistors receive a body biasing voltage. Examples are shown in FIGS. 2-6, in which the transistors M1 and M2 receive the voltage Vbulk.

At action 730, the amplitude of an output clock signal of the oscillator is regulated by the diode-connected transistors. Examples are shown in FIGS. 2-6, in which the transistors M1 and M2 are arranged as a diode clamp to prevent clipping of the output signal Vout.

At action 740, the compensation circuit modulates a body-source voltage (VBS) of the diode-connected transistors. In one example, the compensation circuit includes a series of diodes having a voltage drop that defines the body bias voltage Vbulk. In another example, the compensation circuit has a series of diodes that have a voltage drop that defines the common mode voltage VCM.

At action 750, downstream circuitry adjusts signal processing by conforming to an RC product of the oscillator. For example, the output voltage Vout of the oscillator is a clock signal that is indicative of an RC product of components in the oscillator as well as an other components (such as a filter) on the same substrate. The downstream circuitry receives the clock signal and then adjust the performance of, e.g. a mixer or other filters, conforming to the RC product of the oscillator. In the example of FIG. 1, the digital compensation circuitry 140 provides digital adjustment of the downstream, processing circuit 130 to compensate for expected PVT variation of the baseband filter 112. The example of FIG. 1 assumes that PVT variation of the RC oscillator 116 affects the RC product of the RC oscillator 116 in a way that is indicative of the PVT variation effects on the baseband filter 112.

Method 700 may be performed periodically, at manufacturer of the device, or at other appropriate times.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. A circuit comprising:
an oscillator;
a diode clamp implemented in the oscillator and configured to regulate an amplitude of the oscillator, wherein the diode clamp includes a plurality of diode-connected transistors, each of the diode-connected transistors including a body terminal; and
a compensation circuit in communication with the diode clamp and configured to modulate a body-source voltage of the diode-connected transistors in accordance with a current or voltage level of a transistor in the compensation circuit.

2. The circuit of claim 1, wherein the oscillator comprises a Wien bridge oscillator.

3. The circuit of claim 1, wherein the oscillator receives a common mode voltage, and further wherein the compensation circuit comprises:
a plurality of series-connected diodes outputting a voltage level to the body terminals of the diode-connected transistors.

4. The circuit of claim 3, wherein the series-connected diodes comprises three or more diodes, and wherein the transistor in the compensation circuit comprises one of the diodes in the series-connected diodes.

5. The circuit of claim 1, wherein a voltage level of the body terminals of the diode-connected transistors is in communication with a constant power supply voltage, and wherein the oscillator receives a common mode voltage, and further wherein the compensation circuit comprises:
a plurality of series-connected diodes outputting the common mode voltage to source terminals of the diode-connected transistors.

6. The circuit of claim 5, wherein the series-connected diodes comprises three or more diodes, and wherein the transistor in the compensation circuit comprises one of the diodes in the series-connected diodes.

7. The circuit of claim 1, wherein the diode-connected transistors and the transistor in the compensation circuit comprise NMOS transistors.

8. The circuit of claim 1, wherein the diode-connected transistors are coupled source-to-drain and drain-to-source, and wherein body terminals of the diode-connected transistors are coupled to a common node.

9. The circuit of claim 1, wherein the compensation circuit is configured to modulate the body-source voltage of the diode-connected transistors in accordance with a gate voltage level of the transistor in the compensation circuit.

10. A method performed by a circuit having an oscillator, the method comprising:
receiving a common mode voltage (V_{CM}) at the oscillator, wherein the oscillator includes a plurality of diode-connected transistors receiving V_{CM} at their respective source terminals;
receiving a body bias voltage at body terminals of the diode-connected transistors;
regulating an amplitude of an output clock signal of the oscillator by the diode-connected transistors; and
modulating a body-source voltage (V_{BS}) of the diode-connected transistors in accordance with a voltage or current level of a transistor in a compensation circuit in communication with the oscillator.

11. The method of claim 10, wherein modulating V_{BS} comprises:
modulating the body bias voltage.

12. The method of claim 10, wherein modulating V_{BS} comprises:
modulating V_{CM}.

13. The method of claim 10, wherein modulating V_{BS} comprises:
modulating the body bias voltage and V_{CM}.

14. The method of claim 10, further comprising:
adjusting signal processing by conforming to an RC product of the oscillator.

15. A circuit comprising:
means for generating a clock signal;
means for regulating an amplitude of the clock signal generating means, the regulating means including coupled diodes having diode-connected transistors, each of the diode-connected transistors including a body terminal receiving a body bias voltage; and
means for modulating a body-source voltage of the diode-connected transistors in accordance with a gate voltage level of a transistor in the modulating means.

16. The circuit of claim 15, wherein the clock signal generating means comprises a Wien bridge oscillator.

17. The circuit of claim 15, wherein the clock signal generating means receives a common mode voltage, and further wherein the compensation circuit comprises:
a plurality of series-connected diodes outputting the body bias voltage to the body terminals of the diode-connected transistors.

18. The circuit of claim 17, wherein the series-connected diodes comprises three or more diodes, and wherein the transistor in the modulating means comprises one of the diodes in the series-connected diodes.

19. The circuit of claim 15, wherein the body bias voltage comprises a constant power supply voltage, and wherein the clock generating means receives a common mode voltage, and further wherein the modulating means comprises:
a plurality of series-connected diodes outputting the common mode voltage to source terminals of the diode-connected transistors.

20. The circuit of claim 19, wherein the series-connected diodes comprises three or more diodes, and wherein the transistor in the modulating means comprises one of the diodes in the series-connected diodes.

21. The circuit of claim 15, wherein the diode-connected transistors and the transistor in the modulating means comprise NMOS transistors.

22. The circuit of claim 15, wherein the diode-connected transistors are arranged back-to-back.

23. The circuit of claim 15, wherein the clock generating means receives a common mode voltage at source terminals of the diode-connected transistors;
wherein the modulating means comprises a first plurality of series-connected diodes outputting the body bias voltage; and
the circuit further including a compensation circuit comprising a second plurality of series-connected diodes outputting the common mode voltage.

24. A circuit comprising:
a Wien bridge oscillator;
a diode clamp in communication with the Wien bridge oscillator, the diode clamp including a plurality of diode-connected transistors, each of the diode-connected transistors having a body terminal receiving a body bias voltage and having a source terminal receiving a common mode voltage; and
a compensation circuit in communication with the Wien bridge oscillator, the compensation circuit including a plurality of series-connected diodes having a voltage drop configured to adjust a body-source voltage of the diode connected transistors.

25. The circuit of claim 24, wherein the diode-connected transistors are arranged back-to-back.

26. The circuit of claim 25, wherein the series-connected diodes comprises three or more diodes.

27. The circuit of claim 24, wherein the body bias voltage comprises a constant power supply voltage, and wherein compensation circuit is configured to output the common mode voltage to source terminals of the diode-connected transistors.

28. The circuit of claim 24, wherein the diode-connected transistors and the diodes in the compensation circuit comprise NMOS transistors.

29. The circuit of claim 24, wherein the diode-connected transistors and the diodes in the compensation circuit comprise PMOS transistors.

30. The circuit of claim 24, wherein the compensation circuit is configured to output the body bias voltage;
the circuit further including an additional compensation circuit comprising a second plurality of series-connected diodes outputting the common mode voltage.
